(19) United States
(12) Patent Application Publication
(10) Pub. No.: US 2025/0170899 A1
(43) Pub. Date: May 29, 2025

(54) METHOD AND SYSTEM FOR CURRENT REGULATION AT A RECEIVER OF AN ELECTRIC VEHICLE CONFIGURED FOR WIRELESS POWER TRANSFER

(71) Applicant: Electreon Wireless Ltd., Beit Yanai (IL)

(72) Inventor: Hanan RUMBAK, Mazkeret Batya (IL)

(73) Assignee: Electreon Wireless Ltd., Beit Yanai (IL)

(21) Appl. No.: 19/036,190

(22) Filed: Jan. 24, 2025

Related U.S. Application Data
(63) Continuation-in-part of application No. 17/734,220, filed on May 2, 2022, now Pat. No. 12,275,311.
Application No. 17/734,220 is a continuation of application No. 16/655,395, filed on Oct. 17, 2019, now Pat. No. 11,318,845.
Application No. 16/655,395 is a continuation of application No. 15/198,844, filed on Jun. 30, 2016, now Pat. No. 10,449,865.
Application No. 15/198,844 is a continuation-in-part of application No. PCT/IL2014/051140, filed on Dec. 31, 2014.
(60) Provisional application No. 63/624,510, filed on Jan. 24, 2024.

(30) Foreign Application Priority Data
Dec. 31, 2013 (GB) GB1323160.0

(51) Int. Cl. B60L 5/00; B60L 53/12; B60M 1/10; B60M 3/06; B60M 7/00; H01F 38/14; H02J 50/12; H03H 7/38

(52) U.S. Cl. CPC B60L 5/005; B60L 53/12; B60M 1/10; B60M 3/06; B60M 7/003; H01F 38/14; H02J 50/12; H03H 7/38; B60L 2210/30; Y02T 10/70; Y02T 10/7072; Y02T 90/12; Y02T 90/16

(57) ABSTRACT

A system and method for protecting against overvoltage in a vehicle assembly of an electric vehicle, wherein the vehicle assembly is in communication with a ground assembly as a part of a wireless power transfer system for electric vehicles, are provided herein. The system may include: a communication unit in the vehicle assembly configured to repeatedly transmit a power request signal to the ground assembly; a protection circuitry configured to: detect an overvoltage event across an output of the vehicle assembly; and divert current off the output of the vehicle assembly, into a by-pass circuitry, upon detection of the overvoltage event, wherein upon receiving an indication from the protection circuitry of the overvoltage event, the communication unit stops transmitting the power request signal to the ground assembly

### CROSS REFERENCE TO RELATED APPLICATIONS

This application claims priority from U.S. Provisional Patent Application No. 63/624,510 filed on Jan. 24, 2024 and is also a Continuation-in-Part application of U.S. patent application Ser. No. 17/734,220 which was filed on May 2, 2022 as a Continuation application of U.S. patent application Ser. No. 16/655,395, which was filed on Oct. 17, 2019 as a Continuation application of U.S. patent application Ser. No. 15/198,844, which was filed on Jun. 30, 2016 as a Continuation-in-Part application of PCT Patent Application No. PCT/IL2014/051140, which was filed on Dec. 31, 2014 claiming priority from GB Patent Application No. GB1323160.0, filed on Dec. 31, 2013, all of which are incorporated herein by reference in their entireties.

### FIELD OF THE INVENTION

The present invention relates generally to wireless power transmission in electric vehicles and more specifically to protecting the receiver of electric vehicle from overvoltage.

### BACKGROUND OF THE INVENTION

Prior to setting forth the background of the invention, it would be advantageous to provide some term definitions as follows:

The term ‘electric vehicle’ or EV refers generally to a vehicle powered solely, or in part, by electrical energy stored (e.g., chemically) in a battery, or the like. In the present context, an ‘electric vehicle’ moreover has provision for receiving (e.g., at coils disposed of the underside of the vehicle) a wirelessly induced electromotive force (i.e., voltage) that may be stored, or otherwise utilized to recharge the battery. For an electromagnetically induced voltage to occur, the vehicle (i.e., the ‘conductor’) may be moving relative to a magnetic field which is, for example, projected about the road upon which the vehicle is travelling. Alternatively, the magnetic field may be periodically varied (e.g., through use of alternating current) thereby inducing a voltage at the vehicle.

The term ‘road section’ refers generally to a portion of, for example, a highway or motorway which has been modified to comprise a medium for wirelessly transmitting power (i.e., a ‘power transmitter’). This may mean that the road comprises a plurality of coils embedded beneath the surface of the road section which are operable to emit a magnetic field. In typical arrangements, the medium (coils) may be connected to an alternating current source, e.g. an electrical grid, and may generate a varying magnetic field, thereby inducing a voltage in any proximate conductor.

The term ‘ground assembly” refers generally to a portion of, for example, a road, a highway or motorway which has been modified to comprise a medium for wirelessly transmitting power (i.e., a ‘power transmitter’). This may mean that the road comprises a plurality of coils embedded beneath the surface of the road section which are operable to emit a magnetic field. In typical arrangements, the medium (coils) may be connected to an alternating current source, e.g. an electrical grid, and may generate a varying magnetic field, thereby inducing a voltage in any proximate conductor.

The term ‘vehicle assembly” refers generally to circuitry on board of the electric vehicle which include a receiver to receive the power transmitted from the ground assembly, an energy regulator, as well as other circuitries as needed to ensure the battery of the electric vehicle and then the motor of the electric vehicle receive the energy per their requirements.

FIG. 1 is a block diagram illustrating a prior art wireless power transmission system 100. Wireless power transmission system 100 may include a plurality of electric vehicles 150 comprising an attached power receiver, for example, to an underside of the vehicle. The plurality of electric vehicles may further travel upon a road section 101 having one or more power transmitters 120 disposed, for example, underneath the surface of the road section and fed by power converter 122 connected to an electrical grid. In some embodiments, each power receiver and power transmitter may comprise one or more wound or looped coils coupled, for example, to an alternating current source. In some arrangements, these coils may be operable to emit a static or varying magnetic field into a vicinity about the coils, for example around the road section or portions thereof. As each electric vehicle travels along road section 101, a magnetic field formed by power transmitters in road section 101 induces a voltage in each power receiver and is stored and/or converted by the electric vehicle into, for example, chemical energy in a battery. In alternative embodiments, the induced energy may be immediately used by an engine of the electric vehicle without storage.

On the electric vehicle side, the power receiver is loaded with an electric motor. In the case that the receiver is disconnected from the load, there is a danger of overvoltage since the receiver acts as a current source and as such it is more challenging to regulate it, compared to a voltage source.

There is therefore a need to protect the battery and the motor of the electric vehicle against overvoltage in such cases.

### SUMMARY OF THE PRESENT INVENTION

The present invention provides a system and method for protecting a receiver of a wireless power transmission electric vehicle. The receiver side is equipped with a controlled switch such as a silicon-controlled rectifier (SCR) circuitry which is configured to detect high-voltage, for example in a case that the load is disconnected from the receiver which acts as a current source. In such a case the capacitor of the receiver side is discharged via the SCR eliminating the risk of over-power, thereby improving the reliability of the power receiver as a current source.

These and other advantages of the present invention are set forth in detail in the following description.

### BRIEF DESCRIPTION OF THE DRAWINGS

For a better understanding of the invention and in order to show how it may be implemented, references are made, purely by way of example, to the accompanying drawings in which like numerals designate corresponding elements or sections. In the accompanying drawings:

FIG. 1 is a block diagram showing wireless power transmission system for an electric vehicle on a road in accordance with the prior art;

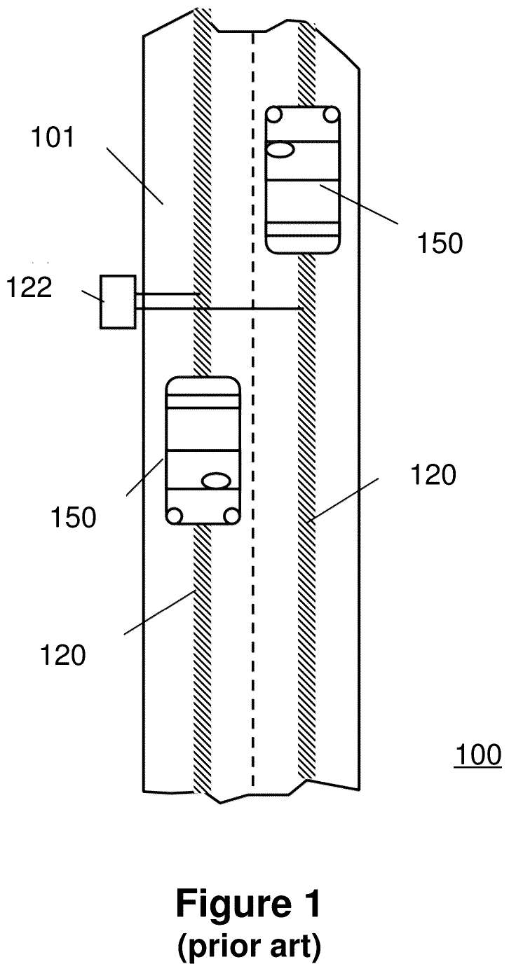

FIG. 2 is a circuit diagram in accordance with some embodiments of the present invention;

FIG. 3 is a circuit diagram in accordance with some embodiments of the present invention;

FIG. 4 is another circuit diagram in accordance with some embodiments of the present invention; and

FIG. 5 is waveform diagram in accordance with some embodiments of the present invention.

### DETAILED DESCRIPTION OF THE INVENTION

With specific reference now to the drawings in detail, it is stressed that the particulars shown are for the purpose of example and solely for discussing the preferred embodiments of the present invention and are presented in the cause of providing what is believed to be the most useful and readily understood description of the principles and conceptual aspects of the invention. In this regard, no attempt is made to show structural details of the invention in more detail than is necessary for a fundamental understanding of the invention. The description taken with the drawings makes it apparent to those skilled in the art how the several forms of the invention may be embodied in practice.

Before explaining the embodiments of the invention in detail, it is to be understood that the invention is not limited in its application to the details of construction and the arrangement of the components set forth in the following descriptions or illustrated in the drawings. The invention is applicable to other embodiments and may be practiced or carried out in various ways. Also, it is to be understood that the phraseology and terminology employed herein is for the purpose of description and should not be regarded as limiting.

The following is a general description of some embodiments of the present invention: according to some embodiments of the present invention, one of the outputs of vehicle assembly controller may connected to a control input of the controlled switch circuitry. The vehicle assembly may further include a communication unit which is controlled by vehicle assembly controller.

In operation, when charging is needed, either static or dynamic, vehicle assembly controller instructs the communication unit to transmit a power request signal to a communication unit of ground assembly. The power request signal may be a modulated signal such that the modulating signal is a series of pulses where the duty cycle of the pulse may indicate the level of power needed and the carrier signal is an RF signal, so the modulated signal is a pulsed RF signal. The modulating signal may also include a unique identification of the EV associated with the vehicle assembly.

On the ground assembly side, a communication unit receives and demodulates the modulate signal and the ground assembly controller may be configured to set ground assembly power circuitry accordingly so that the power applied by ground assembly power circuitry to transmitter coils match the power request signal initiated by vehicle assembly controller and transmitted by communication unit.

The communication between vehicle assembly and ground assembly is unidirectional in nature and may issue power requests but is not receiving any communication from ground assembly.

According to some embodiments of the present invention, the communication unit at the vehicle assembly repeatedly transmits a power request signal to the ground assembly, wherein the power request signal is a modulated signal wherein the modulating signal comprises a unique identifier of the electric vehicle.

According to some embodiments of the present invention, a sensor may be configured to sense whether contactor at the output of the vehicle assembly is open or closes. In case it is open there is a risk of an overvoltage developing at the output of the vehicle assembly and vehicle assembly controller instructs the communication unit to stop requesting any power request.

According to some embodiments of the present invention, a detection circuitry detects an overvoltage event across the output of vehicle assembly.

In some embodiments both aforementioned protection circuitry for stopping the communication may be implemented and according to other embodiments, only one of the aforementioned solutions is implemented.

According to some embodiments of the present invention, an overvoltage event may occur whenever voltage level across an output of the vehicle assembly goes beyond a specific level, or when the voltage gradient across an output of the vehicle assembly goes beyond a specific voltage gradient.

According to some embodiments of the present invention, controlled switch circuitry diverts current off the output of the vehicle assembly, into by-pass circuitry, upon detection of an overvoltage event by detection circuitry across the output of the vehicle assembly.

According to some embodiments of the present invention, the controlled switch circuitry may be operated directly by detection circuitry or via vehicle assembly controller.

According to some embodiments of the present invention, upon receiving an indication from the detection circuitry of an overvoltage event, the communication unit stops transmitting the power request signal to the ground assembly.

Embodiments of the present invention include a vehicle assembly with an overvoltage protection system designed to address an overvoltage event. A ground assembly may include a ground assembly power circuitry which is controlled by ground assembly controller and may be configured to feed transmitter coils with the electrical power required to create the magnetic needed for the wireless power transfer with vehicle assembly.

According to some embodiments of the present invention, the vehicle assembly may be placed on board an electric vehicle and may include receiver coils which may be coupled to transmitter coils. Receiver coils may feed the input of a rectifier which is configured to rectify the alternating current into direct current. The rectifier in turn feeds the input of a direct current (DC) filter which reduces the harmonies of the power signal passing through it. The output of DC filter is also effectively the output of vehicle assembly which may feed the EV battery via contactor and EV battery in turn feeds the motor of the EV.

The following is a more detailed description of embodiments of the present invention with reference to exemplary implementation described by non-limiting circuits.

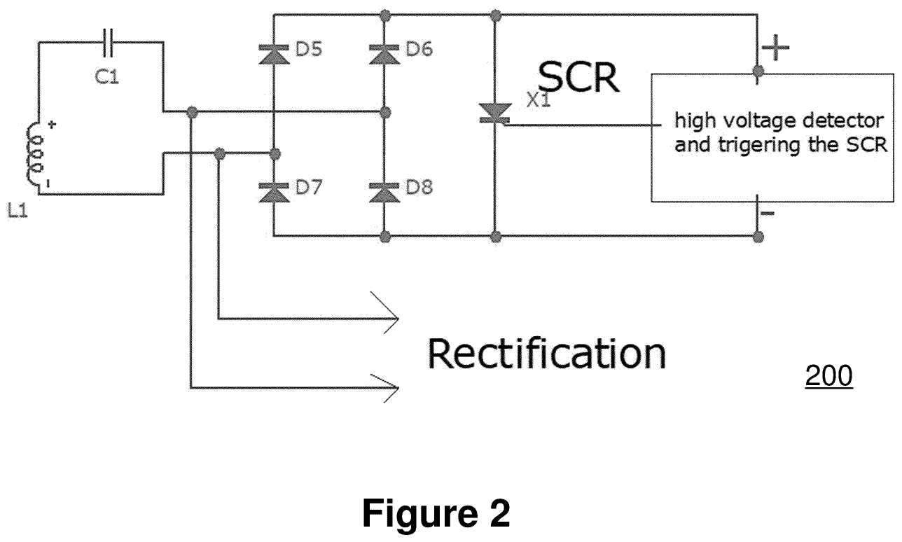

FIG. 2 is a circuit diagram illustrating some embodiments of the present invention. The vehicle assembly which charges the battery in the vehicle is actually a current source, as opposed to a voltage source which can be disconnected with a simple series circuit breaker (create a disconnection) the current source can be disabled by a shortcut.

The following are the situations which require disabling the vehicle assembly from the battery:
The vehicle assembly is not connected to the load, the output connector is not connected.
The electric vehicle initiates disconnection for any reason.
A malfunction while working that disconnects the vehicle from the battery.

In all these situations the current source tries to maintain the current and since it does not see a load, the voltage will rise (this is called an overvoltage event). The outcome will be a destruction of the circuitry.

In accordance with embodiments of the present invention, the technical requirements of an overvoltage protection mechanism for a vehicle assembly may need to successfully operate with the following features:
A resonance frequency of the WPT at approximately 85 kHz.
Currents of up to 150 A flowing through the power coils.
Fast response time, following detection of an overvoltage event, of less than 0.1 mS
Up to voltage of 1000V across the output of the vehicle assembly.

As soon as the vehicle assembly is disconnected from the load while its power receiving coils are within the electromagnetic field coming from the power transmitting coils of the ground assembly, a high voltage quickly develops at the output of the vehicle assembly which is sensed by a detector or a protection circuitry. This voltage produces an ignition pulse that ignites the SCR (or in a general controlled switch, switches the switch to a bypass circuitry) and causes it to short cut between the anode and the cathode. This process takes approximately 50 uS, as long as the power transmitting coils under the road continues to transmit power, the shortcut will remain in place.

Simultaneously with the short circuit or immediately thereafter, the communication unit stops requesting power form the ground assembly and as soon as this happens, the SCR is released and ready for the next cycle. The shortcut flows the entire current that can reach 150 amperes, but since the voltage of the shortcut is low therefore the power that develops is low as well and there is no risk of damage to the circuitry.

Advantageously this simple and reliable circuit saves power electronics that convert the current source to a voltage source.

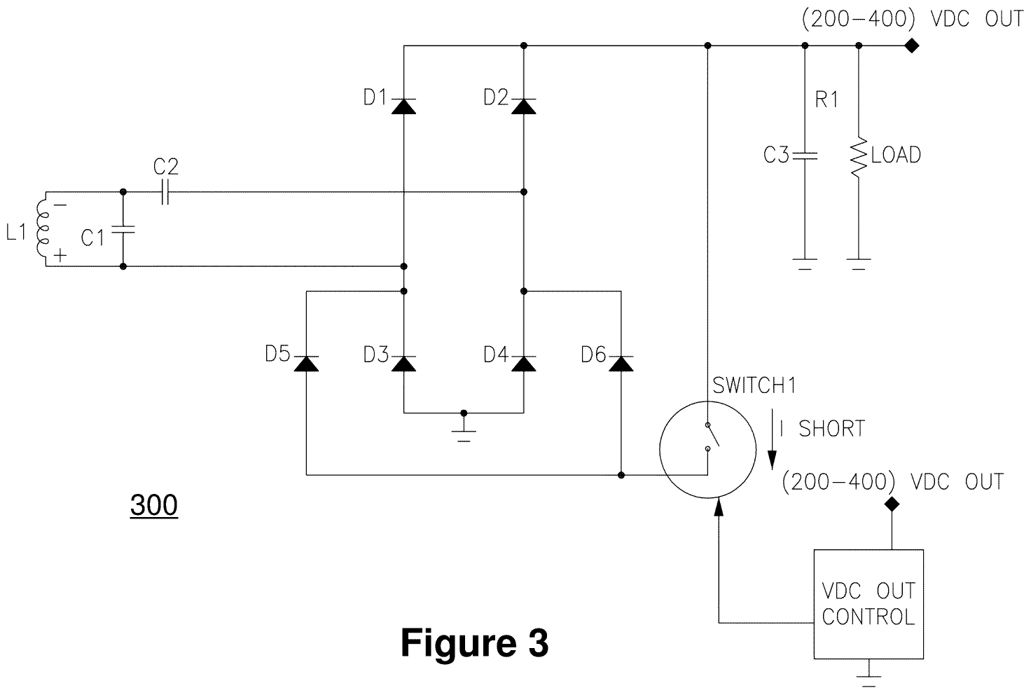

FIG. 3 is a circuit diagram illustrating a mechanism of the voltage regulator at the vehicle side (vehicle assembly) according to some embodiments of the present invention. Voltage regulating circuitry 300 includes a receiver coil L1, a resonance capacitor C1, an impedance load-matching capacitor C2 for load R1. Capacitors C1 and C2 with coil L1 form together a current source, and as such it may be short cut. It is referred herein as feed source. Since the feed source is a current source the output voltage is dependent upon the values of the load resistor R1 and so in the case of a very high load or in a case of a break, the output voltage will become thousands of volts which is destructive.

During regulation, switch 1 (ON position) shortcuts the feed source via diode bridge D1, D2, D5, D6. When switch 1 in in OFF position, a full rectifying of the feed source is carried out via diode bridge D1, D2, D3, D4. VDC out control circuit samples the output voltage and when the voltage reaches the predefined value it switches switch 1 to position ON, load R1 itself does not “see” a short cut and so capacitor C1 maintains its voltage and discharges only via R1. When voltage value decreases to a predefined value, switch 1 shifts back to OFF and the process is repeated again and again. Regulating the output voltage will occur when switch 1 is an electronic switch such as IGBT or MOSFET that can handle the load and the required voltage. It is advantageous to operate it via an insulated push circuit because of the voltage difference between switch 1 and VDC OUT control.

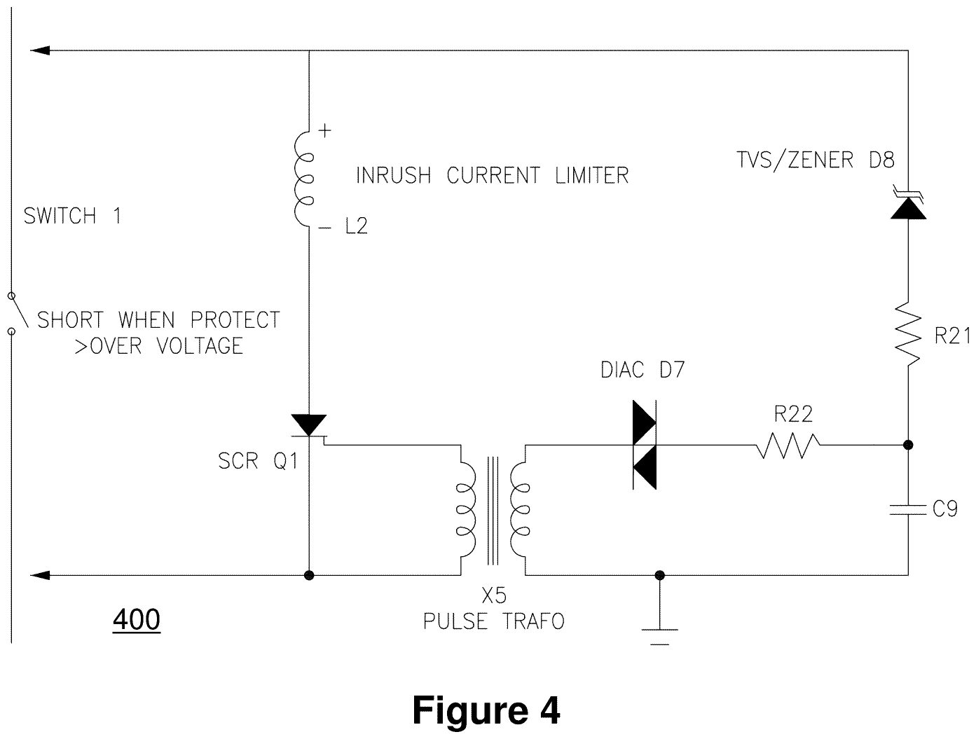

FIG. 4 is a circuit diagram illustrating other aspects relating to protecting against overvoltage at the receiver (vehicle assembly) according to some embodiments of the present invention. Circuit 400 connects in parallel to the circuit described in FIG. 2. Capacitor C9 is charged via resistor R21 when the output voltage reaches the voltage of Zener diode D8. When the voltage over capacitor C9 crosses the discharge point of diode D7, a pulse is generated, and it will flow via the primary windings of transformer X5 and will pass to its secondary windings. Transistor Q1 then will undergo breakdown and will shortcut switch 1. Therefore, the protection is applied when VD7+VD8 reaches an Overvoltage Protection value. This shortcut is maintained until the currency via Q1 is halted in one of two possibilities: external switch (not shown) is OFF or an initiated shortcut over transistor Q1.

Advantageously, this circuit is independent and does not require an external voltage source. Additionally, it is very reliable because it has very few components, and all of them are passive except for transistor Q1.

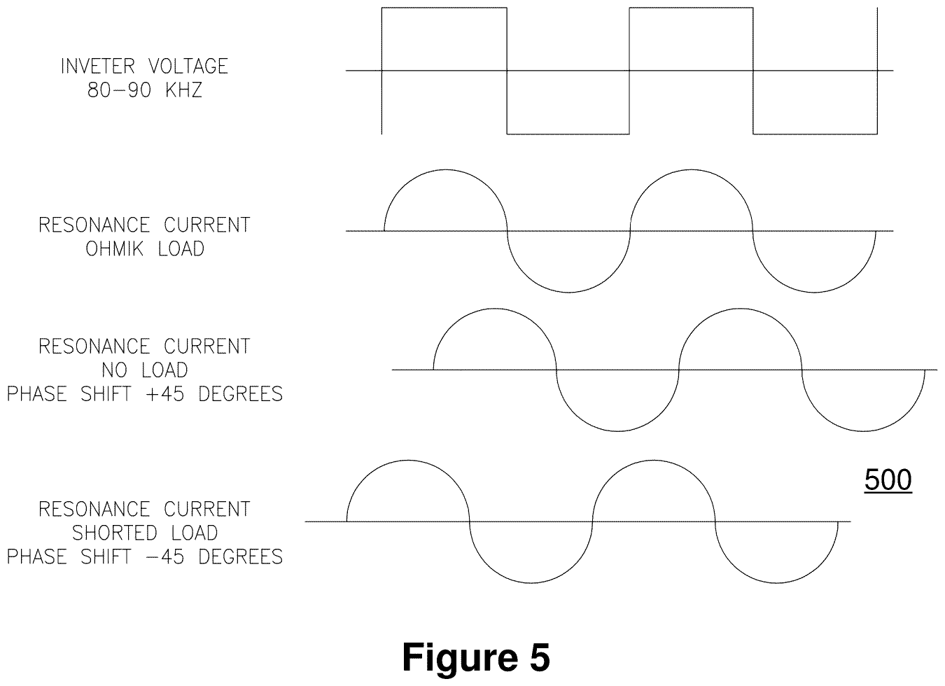

FIG. 5 shows waveform diagram 500 illustrating different aspects relating to the regulating the voltage at the power receiver (vehicle assembly) according to other embodiments of the present invention. In accordance with some embodiments of the present invention, it is possible to regulate the voltage at the receiver by recognizing the phase of the current at the power transmitter segment (ground assembly). Waveform A is the inverter voltage (at the ground assembly) while waveforms B, C, and D are the current phase at the power transmitter segment (ground assembly) as “seen” by the load at the receiver (vehicle assembly). Phases B, C, and D can be easily detected by a current sensor at the ground assembly.

In operation, when switch 1 such as illustrated in FIG. 3 is shortcut, a current sensor at the ground assembly may detect a phase shift (waveform D herein) and disconnects a switch at the ground assembly to ‘OFF’ in response the current flowing to the power transmitting coils of the segment. Disconnecting the current releases transistor Q1 (as in FIG. 4) and the ground assembly switches to communication receiving mode. In case there is incoming communication (e.g., the vehicle assembly located above the power transmit segments transmits a power request signal) then and only the switch in the ground assembly is switched ‘ON’ thus allowing the voltage to rise again at the receiver. This process repeats itself several time for regulating the voltage.

Some embodiments of the present invention may be described as a method of protecting against overvoltage in a vehicle assembly of an electric vehicle, said vehicle assembly being in communication with a ground assembly as a part of a wireless power transfer system for electric vehicles. The method may include the following steps: repeatedly transmitting a power request signal to the ground assembly via a communication unit in the vehicle assembly; detecting an overvoltage event across an output of the vehicle assembly; and diverting current off the output of the vehicle assembly, into a by-pass circuitry, upon detection of the overvoltage event, wherein upon receiving an indication from the protection circuitry of the overvoltage event, stopping transmitting the power request signal to the ground assembly via the communication unit.

According to some embodiments, the detecting may be carried out by a voltage sensor configured to detect the overvoltage event across the output of the vehicle assembly; and wherein the diverting is carried out by a controlled switch configured to divert the current off the output of the vehicle assembly into a by-pass circuitry, upon detection of the overvoltage event.

The method according to claim 13, wherein the overvoltage event comprises a voltage level across the output of the vehicle assembly going beyond the predefined level, or a voltage gradient across the output of the vehicle assembly going above the predefined voltage gradient.

The method according to claim 13, wherein the protection circuitry comprises a silicon-controlled rectifier (SCR).

The method according to claim 16, wherein the SCR comprises a Zener diode and a diode bridge.

The method according to claim 13, further comprising: receiving at a controller, an indication of the overvoltage event, and in response, disabling the transmitting of the power request signal to the ground assembly.

The method according to claim 13, wherein a response time between the detecting and the diverting is less than 0.1 mS.

It should be noted that the method according to embodiments of the present invention may be stored as instructions in a computer readable medium to cause processors, such as central processing units (CPU) to perform the method. Additionally, the method described in the present disclosure can be stored as instructions in a non-transitory computer readable medium, such as storage devices which may include hard disk drives, solid state drives, flash memories, and the like. Additionally, non-transitory computer readable medium can be memory units.

In order to implement the method according to embodiments of the present invention, a computer processor may receive instructions and data from a read-only memory or a random-access memory or both. At least one of aforementioned steps is performed by at least one processor associated with a computer. The essential elements of a computer are a processor for executing instructions and one or more memories for storing instructions and data. Generally, a computer will also include, or be operatively coupled to communicate with, one or more mass storage devices for storing data files. Storage modules suitable for tangibly embodying computer program instructions and data include all forms of non-volatile memory, including by way of example semiconductor memory devices, such as EPROM, EEPROM, and flash memory devices and also magneto-optic storage devices.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit”, “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

The aforementioned flowchart and diagrams illustrate the architecture, functionality, and operation of possible implementations of systems, methods, and computer program products according to various embodiments of the present invention. In this regard, each portion in the flowchart or portion diagrams may represent a module, segment, or portion of code, which comprises one or more executable instructions for implementing the specified logical function(s). It should also be noted that, in some alternative implementations, the functions noted in the portion may occur out of the order noted in the figures. For example, two portions shown in succession may, in fact, be executed substantially concurrently, or the portions may sometimes be executed in the reverse order, depending upon the functionality involved, It will also be noted that each portion of the portion diagrams and/or flowchart illustration, and combinations of portions in the portion diagrams and/or flowchart illustration, can be implemented by special purpose hardware-based systems that perform the specified functions or acts, or combinations of special purpose hardware and computer instructions.

The aforementioned figures illustrate the architecture, functionality, and operation of possible implementations of systems and apparatus according to various embodiments of the present invention. Where referred to in the above description, an embodiment is an example or implementation of the invention. The various appearances of “one embodiment,” “an embodiment” or “some embodiments” do not necessarily all refer to the same embodiments.

Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “some embodiments”, “an embodiment”, “one embodiment” or “other embodiments” means that a particular feature, structure, or characteristic described in connection with the embodiments is included in at least some embodiments, but not necessarily all embodiments, of the inventions. It will further be recognized that the aspects of the invention described hereinabove may be combined or otherwise coexist in embodiments of the invention.

It is to be understood that the phraseology and terminology employed herein is not to be construed as limiting and are for descriptive purpose only.

The principles and uses of the teachings of the present invention may be better understood with reference to the accompanying description, figures and examples.

It is to be understood that the details set forth herein do not construe a limitation to an application of the invention.

Furthermore, it is to be understood that the invention can be carried out or practiced in various ways and that the invention can be implemented in embodiments other than the ones outlined in the description above.

It is to be understood that the terms “including”, “comprising”, “consisting of” and grammatical variants thereof do not preclude the addition of one or more components, features, steps, or integers or groups thereof and that the terms are to be construed as specifying components, features, steps or integers.

If the specification or claims refer to “an additional” element, that does not preclude there being more than one of the additional element.

It is to be understood that where the claims or specification refer to “a” or “an” element, such reference is not construed that there is only one of that element.

It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks.

The term “method” may refer to manners, means, techniques and procedures for accomplishing a given task including, but not limited to, those manners, means, techniques and procedures either known to, or readily developed from known manners, means, techniques and procedures by practitioners of the art to which the invention belongs.

The descriptions, examples and materials presented in the claims and the specification are not to be construed as limiting but rather as illustrative only.

Meanings of technical and scientific terms used herein are to be commonly understood as by one of ordinary skill in the art to which the invention belongs, unless otherwise defined.

The present invention may be implemented in the testing or practice with materials equivalent or similar to those described herein.

While the invention has been described with respect to a limited number of embodiments, these should not be construed as limitations on the scope of the invention, but rather as exemplifications of some of the preferred embodiments. Other or equivalent variations, modifications, and applications are also within the scope of the invention. Accordingly, the scope of the invention should not be limited by what has thus far been described, but by the appended claims and their legal equivalents.

1. A system for protecting against overvoltage in a vehicle assembly of an electric vehicle, said vehicle assembly being in communication with a ground assembly as a part of a wireless power transfer system for electric vehicles, said system comprising:
a communication unit in the vehicle assembly configured to repeatedly transmit a power request signal to the ground assembly;
a protection circuitry configured to:
detect an overvoltage event across an output of the vehicle assembly; and
divert current off the output of the vehicle assembly, into a by-pass circuitry, upon detection of the overvoltage event,
wherein upon receiving an indication from the protection circuitry of the overvoltage event, the communication unit stops transmitting the power request signal to the ground assembly.

2. The system according to claim 1, wherein the protection circuitry comprises a voltage sensor configured to detect the overvoltage event across the output of the vehicle assembly; and a controlled switch configured to divert the current off the output of the vehicle assembly into a by-pass circuitry, upon detection of the overvoltage event.

3. The system according to claim 1, wherein the overvoltage event comprises a voltage level across the output of the vehicle assembly going beyond a predefined level, or a voltage gradient across the output of the vehicle assembly going above the predefined voltage gradient.

4. The system of claim 1, wherein the protection circuitry comprises a silicon-controlled rectifier (SCR).

5. The system according to claim 4, wherein the SCR comprises a Zener diode and a diode bridge.

6. The system according to claim 1, further comprising a controller connected via a bus to the protection circuitry and the communication unit, to receive an indication from of the overvoltage event, and in response, to disable the communication unit thereby disabling the transmitting of the power request signal to the ground assembly.

7. The system according to claim 1, wherein the vehicle assembly comprises a power receipt coils, a resonance circuitry, and a rectifier.

8. The system according to claim 7, wherein the ground assembly comprises an inverter, a resonance circuitry, power transmit coils and a controlled switch.

9. The system according to claim 8, wherein a resonance frequency of the resonance circuitries is approximately 85 kHz.

10. The system according to claim 9, wherein the power transmit coils and the power receipt coils are capable of enduring a current of 150 A flowing therethrough.

11. The system according to claim 10, wherein the vehicle assembly can endure a voltage of 1000V across the output of the vehicle assembly.

12. The system according to claim 11, wherein a response time of the controlled switch of the vehicle assembly, between receipt of the indication of the overvoltage event and the diverting of the current is less than 0.1 mS.

13. A method of protecting against overvoltage in a vehicle assembly of an electric vehicle, said vehicle assembly being in communication with a ground assembly as a part of a wireless power transfer system for electric vehicles, said method comprising:
repeatedly transmitting a power request signal to the ground assembly via a communication unit in the vehicle assembly;
detecting an overvoltage event across an output of the vehicle assembly; and
diverting current off the output of the vehicle assembly, into a by-pass circuitry, upon detection of the overvoltage event,
wherein upon receiving an indication from the protection circuitry of the overvoltage event, stopping transmitting the power request signal to the ground assembly via the communication unit.

14. The method according to claim 13, wherein the detecting is carried out by a voltage sensor configured to detect the overvoltage event across the output of the vehicle assembly; and wherein the diverting is carried out by a controlled switch configured to divert the current off the output of the vehicle assembly into a by-pass circuitry, upon detection of the overvoltage event.

15. The method according to claim 13, wherein the overvoltage event comprises a voltage level across the output of the vehicle assembly going beyond a predefined level, or a voltage gradient across the output of the vehicle assembly going above the predefined voltage gradient.

16. The method according to claim 13, wherein the protection circuitry comprises a silicon-controlled rectifier (SCR).

17. The method according to claim 16, wherein the SCR comprises a Zener diode and a diode bridge.

18. The method according to claim 13, further comprising: receiving at a controller, an indication of the overvoltage event, and in response, disabling the transmitting of the power request signal to the ground assembly.

19. The method according to claim 13, wherein a response time between the detecting and the diverting is less than 0.1 mS.

20. A non-transitory computer readable medium for protecting against overvoltage in a vehicle assembly of an electric vehicle, said vehicle assembly being in communication with a ground assembly as a part of a wireless power transfer system for electric vehicles, the computer readable medium comprising a set of instructions that, when executed, cause at least one computer processor to:
repeatedly instruct a transmission of a power request signal to the ground assembly via a communication unit in the vehicle assembly;
receive a detection of an overvoltage event across an output of the vehicle assembly;
instruct a diversion of current off the output of the vehicle assembly, into a by-pass circuitry, upon detection of the overvoltage event; and
instruct stopping of the transmission of the power request signal to the ground assembly via the communication unit, upon receiving an indication from the protection circuitry of the overvoltage event.
